(19) United States
(12) Patent Application Publication
(10) Pub. No.: US 2009/0072660 A1
(43) Pub. Date: Mar. 19, 2009

(54) Slider That Utilizes Surface Acoustic Waves

(75) Inventor: Shingo Tamaru, Wexford, PA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 11/857,490

(22) Filed: Sep. 19, 2007

(51) Int. Cl. H01L 41/09; G11B 21/02

(52) U.S. Cl. 310/313 R

(57) ABSTRACT

An apparatus includes a slider having a projection extending therefrom wherein the projection includes a transducer formed thereon. The apparatus also includes a surface acoustic wave generator positioned to direct a surface acoustic wave toward the projection. The transducer may be structured and arranged for performing a data storage read and/or write operation. The surface acoustic wave propagates along a surface of the projection in order to provide for the projection to be in contact with a data storage media. A related method is also provided.

### BACKGROUND INFORMATION

Sliders are commonly known devices that generally provide for movement of an object relative to another object. As an example, data storage systems often include a slider that moves relative to a data storage medium to support the read/write process. Data storage systems may use sliders in disc drives as part of, for example, magnetic recording systems, optical recording systems, magneto-optical recording systems, or thermal-assisted recording systems. In general, disc drives may use rigid discs that serve as a storage medium for storage of information in a plurality of circular, concentric data tracks. The discs are mounted on a spindle motor that causes the discs to spin and the surfaces of the discs to pass under respective sliders. It is generally desirable to reduce the height at which a slider flies over a data storage disc, which in turn generally provides for increased data storage capabilities on the data storage disc.

### SUMMARY

An aspect of the present invention is to provide an apparatus including a slider having a projection extending therefrom and a surface acoustic wave generator positioned to direct a surface acoustic wave toward the projection. The projection includes a transducer formed thereon.

Another aspect of the present invention is to provide an apparatus including a data storage media and a slider positioned adjacent the data storage media wherein the slider has a projection extending therefrom. The apparatus also includes a surface acoustic wave generator positioned to direct a surface acoustic wave toward the projection.

A further aspect of the present invention is to provide a method that includes providing a data storage media, positioning a slider adjacent the storage media, and propagating a surface acoustic wave along a surface of the projection that is formed on the slider.

These and various other features and advantages will be apparent from a reading of the following detailed description.

### DRAWINGS

FIG. 1 is an illustration of a data storage system, according to one aspect of the present invention.

FIG. 2 is an illustration of a slider and data storage media, according to one aspect of the present invention.

FIG. 3 is an illustration of an air bearing surface of a slider, according to one aspect of the present invention, according to one aspect of the present invention.

FIG. 4 is an illustration of a surface acoustic wave propagating along a surface, according to one aspect of the present invention.

FIG. 5 is an illustration of a slider projection and surface acoustic wave generator, according to one aspect of the present invention.

FIG. 6 is an illustration of slider projection and surface acoustic wave generator, according to one aspect of the present invention.

FIG. 7 is an illustration of an air-bearing surface of a slider, according to one aspect of the present invention.

### DETAILED DESCRIPTION

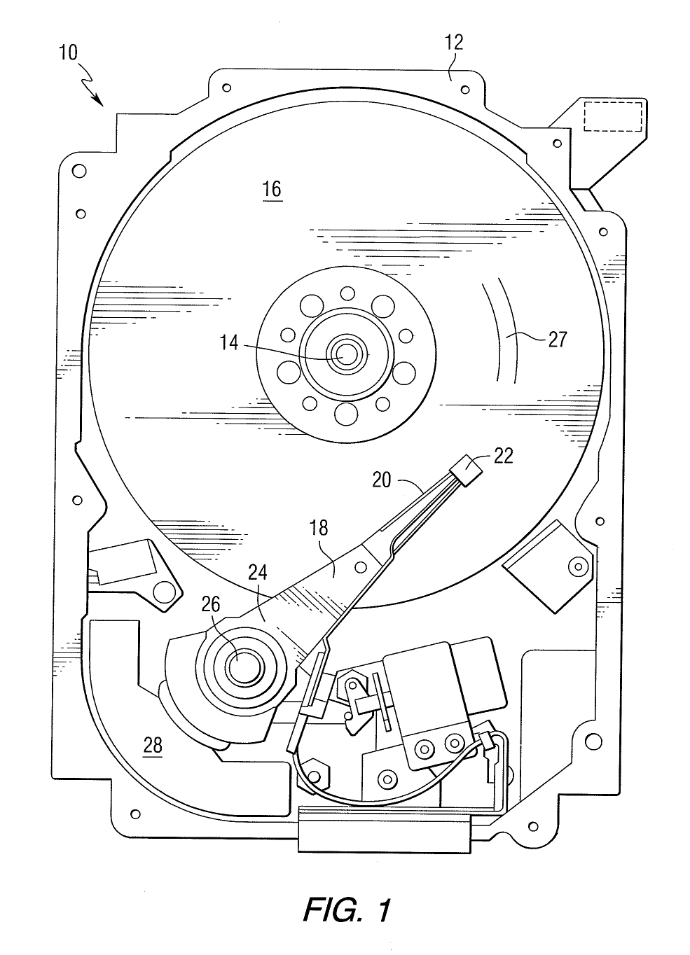

The invention pertains generally to sliders that utilize surface acoustic waves to reduce wear and/or friction between the slider and another surface that may be in contact with the slider. FIG. 1 is an illustration of a data storage system 10 that can include aspects of this invention. While the invention has utility in a data storage system, the invention is not limited to use in data storage systems and it will be appreciated that the description set forth herein is for illustrative purposes only and is not intended to limit the scope of the claims appended hereto. As shown in FIG. 1, the data storage system 10 can include a housing 12 (with the upper portion removed and the lower portion visible in this view) sized and configured to contain the various components of the data storage system 10. The data storage system 10 can also include a spindle motor 14 for rotating at least one storage medium 16 within the housing 12. At least one actuator arm 18 is contained within the housing 12, with each arm 18 having a first end 20 with a slider 22, and a second end 24 pivotally mounted on a shaft by a bearing 26. An actuator motor 28 is located at the arm's second end 24 for pivoting the arm 18 to position the slider 22 over a desired sector or track 27 of the disc 16. The actuator motor 28 is regulated by a controller, which is not shown in this view and is well known in the art.

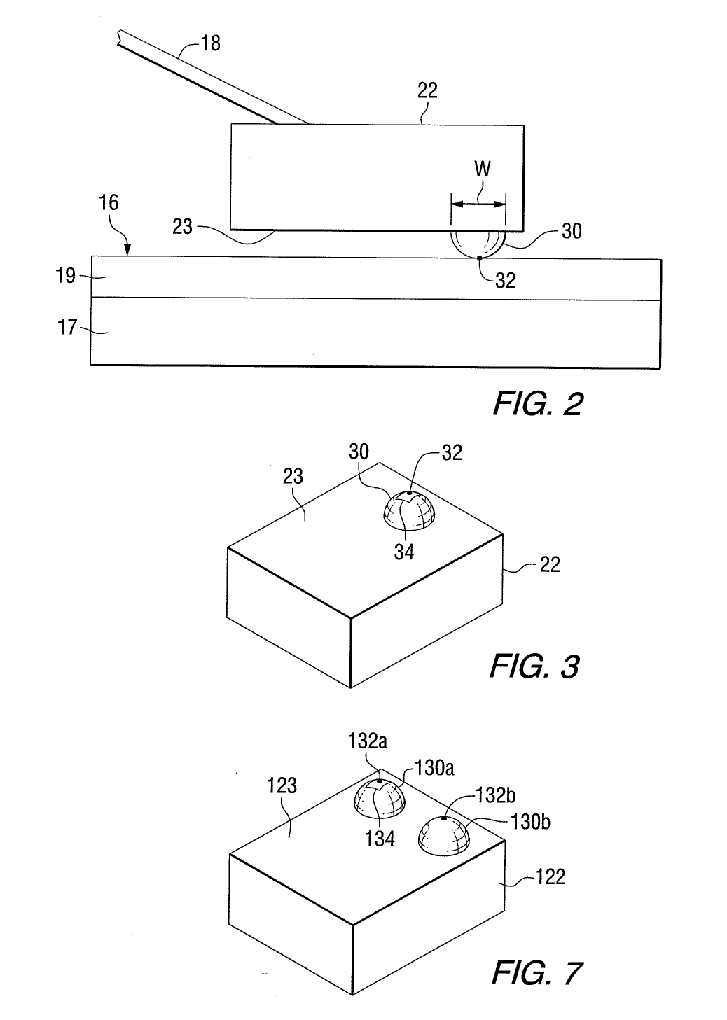

FIG. 2 is an illustration of a slider 22 and data storage media 16 in accordance with an aspect of the invention. The slider 22 is mounted to actuator arm 18 for movement and positioning of the slider 22 relative to the media 16. The media 16 may be, for example, a magnetic, optical, or magneto-optical recording storage media, or any other suitable type data storage media that can be used in association with the slider 22 for reading and/or writing data. The media 16 may move or rotate relative to the slider 22 and may include, but is not limited to, a substrate 17 and a data storage recording layer 19.

As shown in FIGS. 2 and 3, the slider 22 includes a projection 30 formed thereon. In one aspect of the invention, the projection 30 is formed substantially on an air bearing surface (ABS) 23 of the slider 22 such that the projection 30 extends outwardly from the ABS 23. The projection 30 includes a summit point 32. The summit point 32 serves as the point of contact between the projection 30 and the media 16. In accordance with an aspect of the invention, the projection 30 is in contact with the media 16 during movement of the slider 22 and/or movement of the media 16. In accordance with another aspect of the invention, the projection 30 may be in contact with the recording layer 19 of the media 16, i.e. it is not necessary to use any protective or overcoat layers between the recording layer 19 and the slider 22.

The slider 22 and projection 30 may be formed of, for example, alumina, silicon carbide, or silicon dioxide. The slider 22 with the projection 30 formed thereon may be integrally formed using conventional fabrication techniques, or the slider 22 and projection 30 can be separately formed and then connected also using conventional fabrication techniques. For example, photolithography, ion milling, or reactive ion etching may be used to form the desired shape and configuration of the slider 22, ABS 23 and projection 30. The projection 30 may have, for example, a generally hemispherical shape or any other suitable shape that would provide for the projection 30 to extend generally outwardly from the ABS 23 and culminate in a summit point 32 for contacting the media 16 in accordance with the invention. The projection may be formed to have a width, W, in the range of about 1.0 micron to about 1.0 millimeter.

In accordance with another aspect of the invention, FIG. 3 schematically illustrates a transducer 34 formed on the projection 30. The transducer 34 may be, for example, structured and arranged for performing data storage read and/or write operations. By positioning the transducer 34 generally at the summit point 32 of the projection 30, the transducer 34 is in contact with the media 16. This positioning of the transducer 34 eliminates the spacing between the slider 22 and the media 16. Advantageously, this provides for increased storage capabilities due to elimination of the spacing that a read and/or write signal would otherwise need to travel between the slider 22 and the media 16.

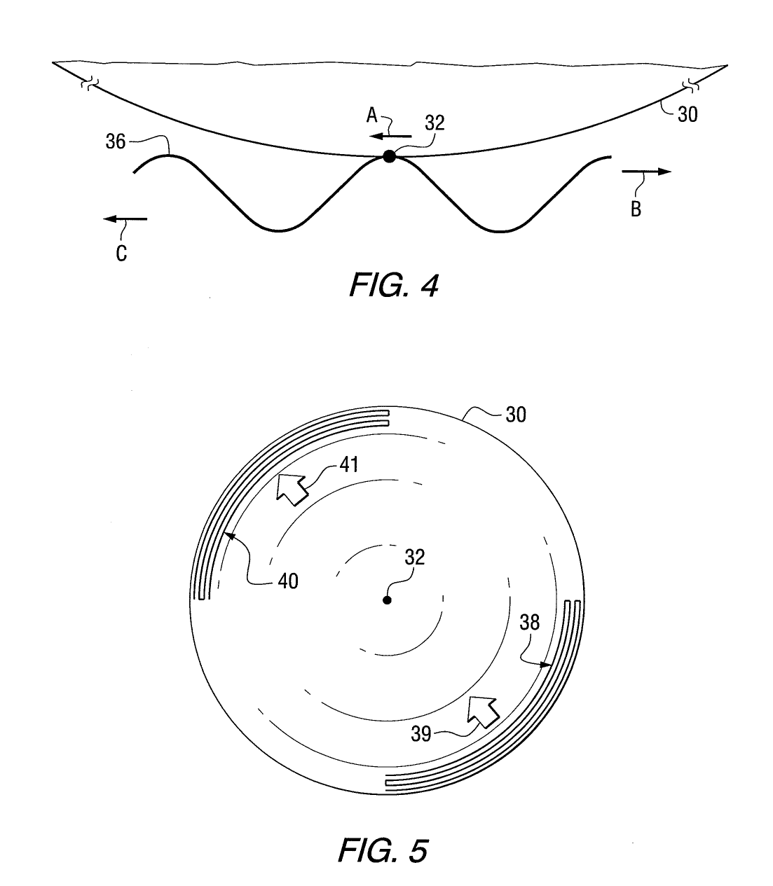

Referring to FIG. 4, there is illustrated a surface acoustic wave (SAW) 36 that is propagated along a surface of the projection 30. In accordance with an aspect of the invention, the SAW 36 allows for the projection 30 to be in contact with the media 16 without resulting in excessive wear to either the projection 30 or the media 16. In general, when a SAW 36 propagates along a surface, such as the surface of the projection 30, a point on the surface, such as the summit point 32, moves along the SAW 36. At the peak of the SAW 36, the summit point 32 moves in a horizontal direction (as indicated by arrow A) opposite to the propagation direction of the SAW 36 (as indicated by arrow B). Therefore, if the SAW 36 is excited on the projection 30 and propagates in the opposite direction as the media 16 rotation direction (as indicated by arrow C), the horizontal velocity of the contact point, i.e. the summit point 32, can match the relative velocity between the slider 22 and the media 16 and the contact point experiences minimal friction with the media 16 and the surface wear can be reduced.

Referring to FIG. 5, there is illustrated an arrangement for generating a SAW in accordance with an aspect of the invention. Specifically, there may be provided an interdigital transducer (IDT) structure that includes a first IDT 38 and a second IDT 40 that are formed on the projection 30. As shown, the first IDT 38 is positioned generally opposite the second IDT 40. The IDT's 38 and 40 may be, for example, one or more electrodes formed in the surface of the projection 30 to receive an input signal having a desired frequency. The first IDT 38 launches or excites the SAW toward the summit point 32 (as indicated by arrow 39) of the projection 30. Directing the SAW toward the summit point 32 of the projection 30 results in the SAW having maximum amplitude at the summit point. The second IDT 40 absorbs or receives the SAW from the first IDT 38 (as indicated by arrow 41). It will be appreciated that additional IDT structures may be positioned on or adjacent the projection 30 for directing a SAW toward the summit point 32.

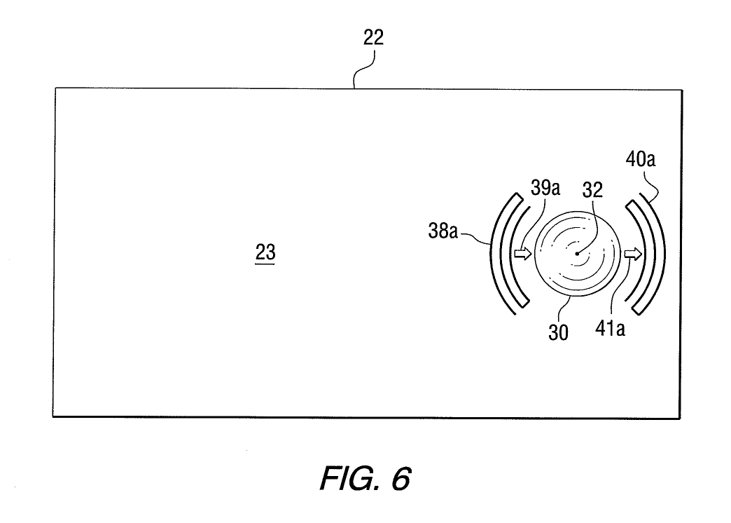

FIG. 6 illustrates an additional aspect of the invention wherein a first IDT 38a and a second IDT 40a are formed on the ABS 23 of the slider 22. The first IDT 38a and the second IDT 40a are positioned adjacent to the projection 30. The first IDT 38a is positioned generally opposite the second IDT 40a. The first IDT 38a launches or excites the SAW toward the summit point 32a (as indicated by arrow 39a) of the projection 30. The second IDT 40a absorbs or receives the SAW from the first IDT 38a (as indicated by arrow 41a). It will be appreciated that additional IDT structures may be positioned on or adjacent the ABS 23 of slider 22 for directing a SAW toward the summit point 32.

Referring to FIG. 7, there is illustrated a slider 122 having an ABS 123 with a first projection 130a and a second projection 130b formed thereon in accordance with an aspect of the invention. Advantageously, having more than one projection allows for additional stability of the slider 122 as it contacts an adjacent surface such as a data storage media (not shown in FIG. 7). The projections 130a and 130b include respective summit points 132a and 132b. A transducer 134 may be formed on the projection 130a, or alternatively the transducer could be formed on the second projection 130b. It will be appreciated that SAW generators such as, for example, the IDT structures described herein and illustrated in FIGS. 5 and 6, may be provided for each projection 130a and 130b in order to direct SAW's onto the projections. It will be appreciated that additional projections may also be provided on the ABS 123

The invention encompasses the method of providing a data storage media (e.g., storage media 16), positioning a slider adjacent to a storage media wherein the slider has a projection (e.g., projection 30), and propagating a SAW along a surface of the projection. As described herein, the method includes contacting the surface of the projection 30 at a summit point 32 thereof with the data storage media 16. In accordance with one aspect of the invention, the projection 30 may be in contact with the recording layer 19 of the data storage media 16. As also described herein, the method may include providing a transducer 34 on the projection 30 wherein the transducer 34 may be structured and arranged for performing read and/or write operations in a data storage system. The method of the invention also includes generating the surface acoustic wave using an interdigital transducer structure such as, for example, interdigital transducer structure 38 and interdigital transducer structure 40, as described herein.

The implementation described above and other implementations are within the scope of the following claims.

1. An apparatus, comprising:
a slider having a projection extending from an air bearing surface of said slider, wherein said projection includes a transducer formed thereon; and
a surface acoustic wave generator positioned to direct a surface acoustic wave toward said projection.

2. The apparatus of claim 1, wherein said surface acoustic wave propagates along a surface of said projection.

3. The apparatus of claim 1, wherein said transducer is structured and arranged for performing a data storage read and/or write operation.

4. The apparatus of claim 1, wherein said surface acoustic wave generator is on said slider.

5. The apparatus of claim 1, wherein said surface acoustic wave generator is on said projection.

6. The apparatus of claim 1, wherein said surface acoustic wave generator includes an interdigital transducer structure to initiate and receive the surface acoustic wave.

7. The apparatus of claim 6, wherein said interdigital transducer structure includes:
a first interdigital transducer for initiating the surface acoustic wave; and
a second interdigital transducer for receiving the surface acoustic wave, said second interdigital transducer opposingly positioned from said first interdigital transducer.

8. The apparatus of claim 1, wherein said projection has a width in the range of about 1.0 micron to about 1.0 millimeter.

9. The apparatus of claim 1, further comprising;
an additional projection extending from said slider; and
an additional surface acoustic wave generator positioned to direct a surface acoustic wave toward said additional projection.

10. An apparatus, comprising:
a data storage media;
a slider positioned adjacent said data storage media, said slider having a projection extending from an air bearing surface of said slider; and
a surface acoustic wave generator positioned to direct a surface acoustic wave toward said projection.

11. The apparatus of claim 10, wherein said projection is in contact with said data storage media.

12. The apparatus of claim 11, wherein said projection is in contact with a recording layer of said data storage media.

13. (canceled)

14. The apparatus of claim 10, wherein said projection includes a transducer formed thereon for performing a data storage read and/or write operation.

15. The apparatus of claim 10, further comprising:
an additional projection extending from said slider; and
an additional surface acoustic wave generator positioned to direct a surface acoustic wave toward said additional projection.

16. A method, comprising:
providing a data storage media;
positioning a slider adjacent said storage media, said slider having a projection extending from an air bearing surface of said slider; and
propagating a surface acoustic wave along a surface of said projection.

17. The method of claim 16, further comprising contacting the surface of said projection with said data storage media.

18. The method of claim 17, further comprising contacting the surface of said projection with a recording layer of said data storage media.

19. The method of claim 16, further comprising providing a transducer on said projection.

20. The method of claim 19, further comprising structuring the transducer to perform a data storage read and/or write operation.
